(19) United States
(12) Patent Application Publication
(10) Pub. No.: US 2026/0059980 A1
(43) Pub. Date: Feb. 26, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Yuting FU, Hefei (CN); Yuan YAO, Hefei (CN); Yingyu FENG, Kunshan (CN); Cheng-Yi LIN, Hefei (CN); Wei-Ju HUANG, Hefei (CN); Yi-Yu LAI, Hefei (CN); Cheng-Chu TSENG, Hefei (CN); Jui-Yang TSAI, Hefei (CN)

(73) Assignees: Hefei Visionox Technology Co., Ltd., Hefei (CN); Visionox Technology Inc., Kunshan (CN)

(21) Appl. No.: 19/305,678

(22) Filed: Aug. 20, 2025

(30) Foreign Application Priority Data
Aug. 26, 2024 (CN) 202411180376.5

(51) Int. Cl. H10K 59/80; H10K 59/122

(52) U.S. Cl. CPC H10K 59/873; H10K 59/122

(57) ABSTRACT

The present application discloses a display panel and a display device. The display panel includes a substrate, an isolation structure, light-emitting units, and a first encapsulation layer. The first encapsulation layer includes encapsulation portions, and each of the encapsulation portions includes a first section and a second section that are connected to each other. The first section is located within an isolation opening, and the second section is located on a side of the isolation structure facing the isolation opening. A surface of a side of the first section away from the substrate and a surface of a side of the second section away from the isolation structure are at least partially connected to define a void space in an enclosing manner. The isolation structure includes a first sub-layer and a second sub-layer that are stacked. The first sub-layer has a top surface away from the substrate.

### CROSS-REFERENCE TO RELATED APPLICATIONS

The present application claims priority to Chinese Patent Application No. 202411180376.5, filed on Aug. 26, 2024 and entitled “DISPLAY PANEL AND DISPLAY DEVICE”, the disclosure of which is incorporated herein by reference in its entirety.

### FIELD

The present application relates to the field of display, and in particular to a display panel and a display device.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

During the preparation of conventional OLED display panels, light-emitting pixel patterning is usually implemented by means of a fine metal mask (FMM). FMM technology is mature and has rich experience in mass production. However, FMM technology also has problems such as limited accuracy, and high costs. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference. However, the usage performance of conventional OLED display products needs to be improved.

### SUMMARY

Embodiments of the present application provide a display panel and a display device, with the aim of improving the use performance of OLED display products.

An embodiment of a first aspect of the present application provides a display panel, including a substrate, an isolation structure, light-emitting units, and a first encapsulation layer. The isolation structure is disposed on a side of the substrate and defines isolation openings in an enclosing manner, where the isolation structure includes a first sub-layer and a second sub-layer located on a side of the first sub-layer away from the substrate, the first sub-layer including a top surface away from the substrate and sidewalls facing the isolation openings, and the second sub-layer protruding from the sidewalls toward the isolation openings by a length a. At least part of each light-emitting unit is located within each corresponding isolation opening. The first encapsulation layer includes encapsulation portions, where each of the encapsulation portions includes a first section and a second section that are connected to each other. The first section is located within the isolation opening and disposed on a side of the light-emitting unit away from the substrate, and the second section is located on a side of the isolation structure facing the isolation openings. A surface of a side of the first section away from the substrate and a surface of a side of the second section away from the isolation structure are at least partially connected to define a void space in an enclosing manner, where within the same isolation opening, an orthographic projection of the void space on the substrate has a first boundary away from the isolation structure, an orthographic projection of the top surface on the substrate has a second boundary, and a distance between the first boundary and the second boundary is b, and b>a.

An embodiment of the first aspect of the present application further provides a display panel, including a substrate, pixel defining portions, an isolation structure, light-emitting units, and a first encapsulation layer. The pixel defining portions are disposed on a side of the substrate. The isolation structure is located on a side of the pixel defining portions away from the substrate and defining isolation openings in an enclosing manner, and the isolation structure includes a first sub-layer and a second sub-layer located on a side of the first sub-layer away from the substrate, the first sub-layer including a top surface away from the substrate and sidewalls facing the isolation openings, and the second sub-layer protruding from the sidewalls toward the isolation openings. The light-emitting units are at least partially located within the isolation openings. The first encapsulation layer includes encapsulation portions, where each of the encapsulation portions includes a first section and a second section that are connected to each other. The first section is located within the isolation opening and disposed on a side of the light-emitting unit away from the substrate, and the second section is located on a side of the isolation structure facing the isolation openings. A surface of a side of the first section away from the substrate and a surface of a side of the second section away from the isolation structure are at least partially connected to define a void space in an enclosing manner. The pixel defining portion has a first orthographic projection on the substrate, the second sub-layer has a second orthographic projection on the substrate, and the first orthographic projection includes a projection portion outside the second orthographic projection. An orthographic projection of the second section on the substrate has a third boundary facing the isolation openings, and the third boundary is located within the projection portion.

An embodiment of a second aspect of the present application provides a display device, including a display panel of any of the above embodiments.

### BRIEF DESCRIPTION OF THE DRAWINGS

FIG. 1 is a structural schematic partial diagram of an isolation structure of a display panel according to an embodiment of the present application;

FIG. 2 is a partial sectional view of a display panel according to an embodiment of the present application;

FIG. 3 is an enlarged view of part A of FIG. 2;

FIG. 4 is a partial sectional view of a display panel according to another embodiment of the present application;

FIG. 5 is a structural schematic diagram of a first section of a display panel according to an embodiment of the present application; and

FIG. 6 is a partial sectional view of a display panel according to yet another embodiment of the present application.

### LIST OF REFERENCE SIGNS

1: substrate;
2: pixel defining layer; 21: pixel defining portion; 22: pixel opening;
3: isolation structure; 30: isolation opening; 31: first sub-layer; 311: top surface; 32: second sub-layer; 33: third sub-layer;
4: light-emitting layer; 41: light-emitting unit;
5: first encapsulation layer; 50: encapsulation portion; 51: first section; 511: main body portion; 5111: first part; 5112: second part; 512: support portion; 52: second section; 521: first portion; 522: second portion; 53: third section; 500: void space; 510: connecting region; 5100: first boundary; 5200: second boundary; 5300: third boundary; 5400: fourth boundary;
6: second encapsulation layer; 61: support structure; 71: first electrode layer; 711: first electrode; 72: second electrode layer; 721: second electrode; and 8: third encapsulation layer.

### DETAILED DESCRIPTION OF THE EMBODIMENTS

Embodiments of the present application provide a display panel and a display device. Various embodiments of the display panel and the display device will be described below with reference to figures.

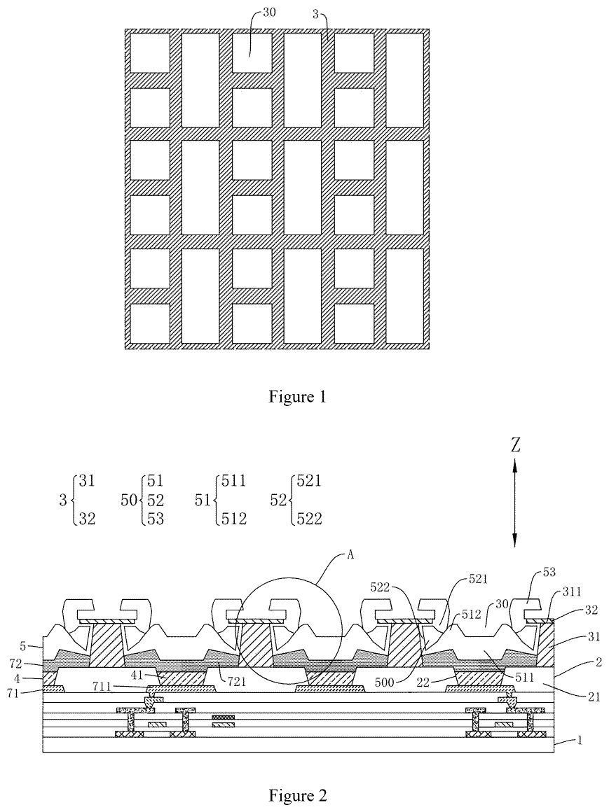

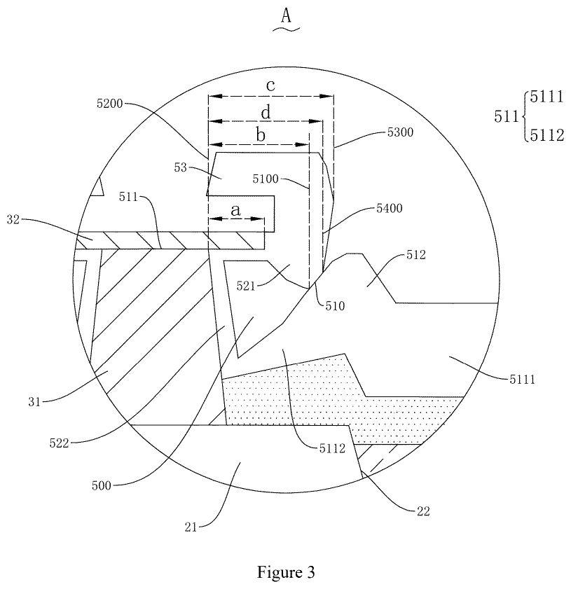

Referring to FIGS. 1-3 together, FIG. 1 is a structural schematic partial diagram of an isolation structure of a display panel according to an embodiment of the present application; FIG. 2 is a partial sectional view of a display panel according to an embodiment of the present application; and FIG. 3 is an enlarged view of part A of FIG. 2.

As shown in FIGS. 1-3, an embodiment of a first aspect of the present application provides a display panel. The display panel includes a substrate 1, an isolation structure 3, a light-emitting layer 4, and a first encapsulation layer 5. The isolation structure 3 is disposed on a side of the substrate 1 and defines isolation openings 30 in an enclosing manner. The isolation structure 3 includes a first sub-layer 31 and a second sub-layer 32 located on a side of the first sub-layer 31 away from the substrate 1. The first sub-layer 31 includes a top surface 311 away from the substrate 1 and sidewalls facing the openings. The second sub-layer 32 protrudes from the sidewalls toward the isolation openings 30 by a length a. The light-emitting layer 4 includes light-emitting units 41 which are at least partially located within the isolation openings 30. The first encapsulation layer 5 includes encapsulation portions 50 for encapsulating the light-emitting units 41. Each of the encapsulation portions 50 includes a first section 51 and a second section 52 that are connected to each other. The first section 51 is located within the isolation opening 30 and disposed on a side of the light-emitting unit 41 away from the substrate 1, and the second section 52 is located on a side of the isolation structure 3 facing the isolation opening 30. A surface of a side of the first section 51 away from the substrate 1 and a surface of a side of the second section 52 away from the isolation structure 3 are at least partially connected to define a void space 500 in an enclosing manner. In the same isolation opening 30, an orthographic projection of the void space 500 on the substrate 1 has a first boundary 5100 away from the isolation structure 3, an orthographic projection of the top surface 311 on the substrate 1 has a second boundary 5200, and a distance between the first boundary 5100 and the second boundary 5200 is b, where b>a.

In one embodiment, the orthographic projection of the void space 500 on the substrate 1 has the first boundary 5100 away from the isolation structure 3 may be understood as that: a junction between the surface of the side of the first section 51 away from the substrate 1 and the surface of the side of the second section 52 away from the isolation structure 3 is defined as a connecting region 510, where an orthographic projection of the connecting region 510 on the substrate 1 includes two boundaries, where the boundary closer to the isolation structure 3 coincides with the first boundary 5100, and the two boundaries are the same boundary. That is, the first boundary 5100 is formed by a connection between the surface of the side of the first section 51 away from the substrate 1 and the surface of the side of the second section 52 away from the isolation structure 3.

In one embodiment, the directions of the orthographic projections of the above-mentioned structures on the substrate 1 may refer to the Z-axis direction in FIG. 2, and the direction indicated by the Z-axis may also be a thickness direction of the display panel.

In one embodiment, as shown in FIG. 1, the isolation structure 3 may be grid-shaped to facilitate the division of subpixels of the display panel by the isolation structure 3. Hollowed regions of the grid-shaped isolation structure 3 may be the isolation openings 30.

The display panel according to this embodiment of the present application includes the substrate 1, the isolation structure 3, the light-emitting units 41, and the first encapsulation layer 5. The isolation structure 3 is disposed on a side of the substrate 1 and defines the isolation openings 30 in an enclosing manner. The light-emitting units 41 are at least partially located within the isolation openings 30. The isolation structure 3 is used to divide the subpixels of the display panel. The isolation structure 3 is disposed on the substrate 1 and defines the isolation openings 30 in an enclosing manner to separate the light-emitting layer 4 into the light-emitting units 41 that are disconnected from each other, thereby reducing crosstalk between charge carriers in the light-emitting layer 4 and improving the display effect of the display panel. Moreover, the light-emitting units 41 may be prepared without the use of a precision mask, which can reduce the development and use of the precision mask and lower preparation costs.

The first encapsulation layer 5 is disposed on a side of the light-emitting units 41 away from the substrate 1. The first encapsulation layer 5 includes the first sections 51 and the second sections 52. The first sections 51 are located within the isolation openings 30 and disposed on the side of the light-emitting units 41 away from the substrate 1, and the second sections 52 are located on the side of the isolation structure 3 facing the isolation openings 30. The first encapsulation layer 5 may be used to encapsulate the light-emitting units 41. Provisions are made that the surface of the side of the first section 51 away from the substrate 1 and the surface of the side of the second section 52 away from the isolation structure 3 are at least partially connected and the first section 51 and the second section 52 defines the void space 500 in an enclosing manner and forms the connecting region 510 to allow the first section 51 to provide effective support to the second section 52, and the second section 52 is less likely to be detached from the isolation structure 3, which can better improve an encapsulation effect of the first encapsulation layer 5 on the display panel.

The second sub-layer 32 protrudes toward the isolation opening 30 beyond the first sub-layer 31. Along a direction perpendicular to the substrate 1, a distance by which the second sub-layer 32 protrudes toward the isolation opening 30 beyond the first sub-layer 31 is a. The distance between the first boundary 5100 of the orthographic projection of the void space 500 away from the isolation structure 3 and the second boundary 5200 of the top surface 311 of the first sub-layer 31 is b. By defining b>a, a connection between the first section 51 and the second section 52 can be located outside the first sub-layer 31, and during the preparation of the first encapsulation layer 5, influences caused by a sealed structure formed by the connection between the first section 51 and the second section 52 on the preparation of the first encapsulation layer 5 can be reduced, allowing a material for preparing the first encapsulation layer 5 to be first deposited uniformly on the isolation structure 3 to form a complete encapsulation structure, thereby improving the yield and usage performance of the display panel.

In one embodiment, the first encapsulation layer 5 may be prepared by a chemical vapor deposition (CVD) process.

Referring to FIG. 3, in some embodiments, 1.5a≤b≤2.5a. By defining b to be no less than 1.5a, along the direction perpendicular to the substrate 1, the distance between the connecting region 510 and the second sub-layer 32 can be at least 0.5a, thereby further reducing the influences of the sealed structure on the preparation of the first encapsulation layer 5. By defining b to be no more than 2.5a, problems can be reduced that the connection between the first sub-layer 31 and the second sub-layer 32 is excessively away from the second sub-layer 32, it is difficult to form the void space 500, more encapsulation material is needed, and encapsulation failure is likely to occur. This embodiment further improves the encapsulation effect of the first encapsulation layer 5. For example, the value of b may be 1.5a, 1.8a, 2a, 2.2a, or 2.5a. In one embodiment, b=2a.

In one embodiment, the display panel further includes a second encapsulation layer 6 and a third encapsulation layer 8 that are disposed on a side of the first encapsulation layer 5 away from the substrate 1, where a material of the second encapsulation layer 6 may include an organic material to impart the second encapsulation layer 6 relatively good flowability, and a surface of the side of the second encapsulation layer 6 away from the substrate 1 is flat. A material of the third encapsulation layer 8 may include an inorganic material to further improve the encapsulation effect of the display panel. In one embodiment, the second encapsulation layer 6 may be prepared by ink jet printing (IJP) technology. The third encapsulation layer 8 may be prepared by a chemical vapor deposition process.

In one embodiment, the display panel further includes a touch layer, a polarizing layer and a cover plate that are disposed on the third encapsulation layer 8. The touch layer may be used to enable touch operation of the display panel, the polarizing layer may be used to filter light to improve the display effect of the display panel, and the cover plate may be used to protect underlying film layers to increase the structural strength of the display panel.

Referring to FIG. 2, in some embodiments, the display panel further includes a first electrode layer 71 and a second electrode layer 72. The first electrode layer 71 includes first electrodes 711 disposed between the substrate 1 and the light-emitting units 41, and the second electrode layer 72 includes second electrodes 721 located between the light-emitting units 41 and the encapsulation portions 50. One of the first electrodes 711 and the second electrodes 721 serve as anodes and the others serve as cathodes to drive the light-emitting units 41 to emit light. An embodiment of the present application where the first electrodes 711 are used as the anodes of the display panel and the second electrodes 721 are used as the cathode of the display panel is exemplified.

In some embodiments, a material of the isolation structure 3 includes a conductive material, and the second electrodes 721 are connected to the isolation structure 3. The isolation structure 3 separates the second electrode layer 72 to form the second electrodes 721 spaced apart from each other, and the second electrodes 721 spaced apart from each other are electrically connected by the isolation structure 3 to form a continuous electrode to ensure normal light emission of the light-emitting units 41. In one embodiment, a material of the first sub-layer 31 may include a conductive material, and the second electrodes 721 may be connected to the first sub-layer 31, and the second electrodes 721 of adjacent subpixels can be electrically connected by the first sub-layer 31.

In one embodiment, during vapor deposition of the light-emitting layer 4 and the second electrode layer 72 of the display panel, the second sub-layer 32 can blocks at least part of materials for preparing the light-emitting layer 4 and the second electrode layer 72, to separate the light-emitting layer 4 and the second electrode layer 72 between adjacent subpixels, facilitate formation of spaced light-emitting units 41 located within the isolation openings 30 and facilitate formation of spaced second electrodes 721 located within the isolation openings 30, thereby eliminating the need for a high-precision mask during the vapor deposition of the light-emitting layer 4 and the second electrode layer 72 of the display panel. For example, this eliminates the need for a fine metal mask (FMM) during the vapor deposition of the light-emitting layer 4 and the second electrode layer 72, thus effectively reducing preparation costs of the display panel.

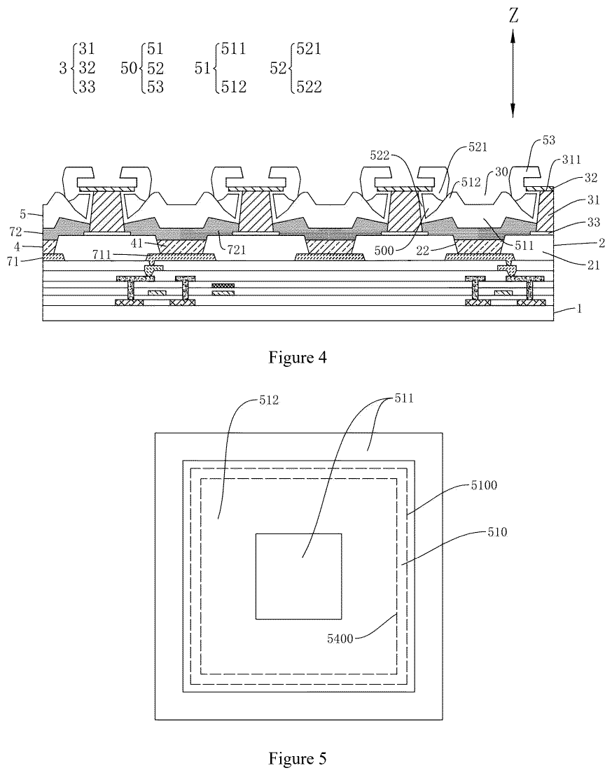

Referring to FIG. 4, FIG. 4 is a partial sectional view of a display panel according to another embodiment of the present application.

Referring to FIG. 4, in some embodiments, the isolation structure 3 further includes a third sub-layer 33 disposed on a side of the first sub-layer 31 facing the substrate 1. The third sub-layer 33 protrudes toward the isolation opening 30 beyond the first sub-layer 31. A material of the third sub-layer 33 may include a conductive material, and the second electrodes 721 may be connected to the third sub-layer 33, and the second electrodes 721 of adjacent subpixels can be electrically connected by the third sub-layer 33. By configuring the third sub-layer 33 to protrude toward the isolation opening 30 beyond the first sub-layer 31, the third sub-layer 33 may have an increased size to facilitate connection of the second electrodes 721.

In one embodiment, the light-emitting unit 41 may include a hole inject layer (HIL), a hole transport layer (HTL), a light-emitting structure, an electron inject layer (EIL), and an electron transport layer (ETL).

In some embodiments, an array layer may be further included between the substrate 1 and the light-emitting layer 4, where the array layer may include drive circuits. For example, the array layer may include a first conductive layer, a second conductive layer and a third conductive layer that are stacked and disposed on a side of the substrate 1. An insulation layer is provided between adjacent conductive layers. By way of example, the pixel drive circuits disposed on the array layer include transistors and storage capacitors. Each of the transistors includes a semiconductor, a gate, a source and a drain. Each of the storage capacitor includes a first plate and a second plate. As an example, the gate and the first plate may be located in the first conductive layer, the second plate may be located in the second conductive layer, and the source and the drain may be located in the third conductive layer.

Referring to FIGS. 2 and 3, in some embodiments, the display panel further includes a pixel defining layer 2 disposed on a side of the isolation structure 3 close to the substrate 1. The pixel defining layer 2 includes pixel defining portions 21, and pixel openings 22 defined by the pixel defining portions 21 in an enclosing manner. An orthographic projection of each pixel opening 22 on the substrate 1 is located within the orthographic projection of the isolation opening 30 on the substrate 1, and the light-emitting units 41 are at least partially located within the pixel openings 22. Each pixel defining portion 21 has a first orthographic projection on the substrate 1, the second sub-layer 32 has a second orthographic projection on the substrate 1, and the first orthographic projection includes a projection portion outside the second orthographic projection. An orthographic projection of the second section 52 on the substrate 1 has a third boundary 5300 facing the isolation openings 30, and the third boundary 5300 is located within the projection portion.

A recess is formed in a region where each pixel opening 22 is located. Structures such as the light-emitting units 41 and the first encapsulation layer 5 adaptively conform to the recesses of the pixel openings 22 when being deposited on the pixel defining layer 2. When the connection between the second section 52 and the first section 51 is located in a recessed region of the first section 51, with the influences from the recessed structure, the connecting region 510 is arranged away from the second section 52, which is likely to lead to connection failure between the first section 51 and the second section 52 and thus encapsulation failure of the first encapsulation layer 5.

In these embodiments, the third boundary 5300 is defined to be located within the projection portion, that is, the third boundary 5300 is located directly above the pixel defining portion 21, the recess of the pixel opening 22 is avoided, improving the encapsulation reliability of the first encapsulation layer 5.

As shown in FIG. 3, in some embodiments, within the same isolation opening 30, a distance between the third boundary 5300 and the second boundary 5200 is c, where b<c.

In these embodiments, by defining that b is less than c, the connection between the second section 52 and the first section 51 can avoid a region where the pixel opening 22 is located in the thickness direction of the display panel. That is, the orthographic projection of the connecting region 510 on the substrate 1 and an orthographic projection of the pixel opening 22 on the substrate 1 have no overlap therebetween. As a result, the connecting region 510 is mainly located above the flat pixel defining portion 21, which reduces influences of the pixel opening 22 structure on the sealed structure formed by the connection between the second section 52 and the first section 51, to enable the first section 51 to more stably support the second section 52, improving the encapsulation reliability of the first encapsulation layer 5 and thus the yield and usage performance of the display panel. In one embodiment, the orthographic projection of the connecting region 510 on the substrate 1 is spaced apart from the orthographic projection of the pixel opening 22 on the substrate 1.

In one embodiment, along a direction away from the substrate 1, an opening area of the pixel opening 22 gradually increases. The pixel opening 22 configured thus facilitate climbing of the light-emitting unit 41 and the second electrode 721, thereby increasing a light-emitting area of the light-emitting unit 41, and facilitating formation of a continuous electrode through overlaps between the second electrodes 721 and the isolation structure 3. The first section 51 located on the pixel opening 22 is recessed toward the pixel opening 22, that is, the top surface 311 of the first section 51 has an inner surface located in the recessed region, and an outer surface located outside the recessed region. By defining that b is less than c, the connecting region 510 can be located on the outer surface, avoiding poor encapsulation due to the connecting region 510 being on the inner surface.

Referring to FIGS. 3 and 5, In one embodiment, the orthographic projection of the connecting region 510 on the substrate 1 includes the first boundary 5100 and a fourth boundary 5400. The fourth boundary 5400 is located on a side of the first boundary 5100 away from the isolation structure 3, and a distance between the fourth boundary 5400 and the second boundary 5200 is d, where d≤c. In one embodiment, both the first boundary 5100 and the fourth boundary 5400 are annular in shape, with the fourth boundary 5400 located inside the first boundary 5100, that is, the fourth boundary 5400 has a smaller size than the first boundary 5100, and the first boundary 5100 is located closer to the isolation structure 3 than the fourth boundary 5400.

In these embodiments, by defining d≤c, the connecting regions 510 can be located on the pixel defining portions 21, thereby avoiding the pixel openings 22. That is, the connecting regions 510 are located above the pixel defining portions 21, to enable the first sections 51 to more stably support the second sections 52, and improve the encapsulation reliability of the first encapsulation layer 5 and thus the yield and usage performance of the display panel.

Referring to FIG. 2, in some embodiments, the first section 51 includes a main body portion 511 and a support portion 512. The support portion 512 is located on a side of the main body portion 511 away from the substrate 1 and extends toward the second section 52. The connecting region 510 is located at the support portion 512. The support portion 512 is connected to the second section 52 to facilitate the involvement of the first section 51 and the second section 52 in collectively defining the void space 500 in an enclosing manner.

In one embodiment, an end of the main body portion 511 facing the isolation structure 3 is connected to an end of the second section 52 facing the substrate 1, and the void space 500 can be defined by the main body portion 511, the support portion 512, and the second section 52 in an enclosing manner and that two connections are formed between the first section 51 and the second section 52, which can better improve the structural stability of the first encapsulation layer 5, further makes it less likely to be detached from the isolation structure 3, and can better improve the encapsulation effect of the first encapsulation layer 5 on the display panel.

In one embodiment, referring to FIG. 3, the main body portion 511 includes a first sub-portion 5111 and a second sub-portion 5112 that are connected to each other. An orthographic projection of the first sub-portion 5111 on the substrate 1 is located within the orthographic projection of the pixel opening 22 on the substrate 1, and an orthographic projection of the second sub-portion 5112 on the substrate 1 is located within the orthographic projection of the pixel defining portion 21 on the substrate 1. The end of the main body portion 511 facing the isolation structure 3 being connected to the end of the second section 52 facing the substrate 1 may refer to that an end of the second sub-portion 5112 facing the isolation structure 3 is connected to the end of the second section 52 facing the substrate 1. The void space 500 may be defined by the second sub-portion 5112, the support portion 512 and the second section 52 in an enclosing manner.

In one embodiment, an orthographic projection of the support portion 512 on the substrate 1 may at least partially overlap with the orthographic projection of the pixel defining portion 21 on the substrate 1, that is, at least part of the support portion 512 may be located on a side of the pixel defining portion 21 away from the substrate 1, and the pixel defining portion 21 can raise the position of the support portion 512 to facilitate the connection between the support portion 512 and the second section 52.

Referring to FIG. 3, in some embodiments, the second section 52 includes a first portion 521 disposed on a side of the second sub-layer 32 facing the isolation openings 30. The support portion 512 is connected to the first portion 521 to define the void space 500 in an enclosing manner. The first portion 521 extends toward a side away from the substrate 1.

The first portion 521 extending toward a side away from the substrate 1 may be understood as that an end of the first portion 521 away from the substrate 1 may extend upwardly beyond the second sub-layer 32.

In one embodiment, at least part of the void space 500 is located between the second sub-layer 32 and the substrate 1. Since the second sub-layer 32 is configured to protrude toward the isolation opening 30 beyond the first sub-layer 31, the first portion 521 disposed on the side of the second sub-layer 32 facing the isolation opening 30 can be more easily connected to the support portion 512, i.e., facilitating the support portion 512 supporting the second section 52, thereby making the second section 52 less likely to be detached from the isolation structure 3.

In one embodiment, the second section 52 further includes a second portion 522 disposed on a side of the first sub-layer 31 facing the isolation opening 30. The first portion 521 is spaced apart from the main body portion 511, and the second portion 522 is spaced apart from the support portion 512. The first portion 521, the second portion 522, the support portion 512, and the main body portion 511 define the void space 500 in an enclosing manner.

In one embodiment, an end of the second portion 522 away from the substrate 1 may be connected to the first portion 521. In one embodiment, the end of the second portion 522 away from the substrate 1 may be integrally connected to the first portion 521 that covers a surface of a side of the second sub-layer 32 facing the substrate 1. In one embodiment, an end of the second portion 522 facing the substrate 1 may be connected to the end of the main body portion 511 facing the isolation structure 3. For example, the end of the second portion 522 facing the substrate 1 may be connected to the end of the second sub-portion 5112 facing the isolation structure 3. In one embodiment, the void space 500 may be defined by the first portion 521, the second portion 522, the second sub-portion 5112 and the support portion 512 in an enclosing manner.

Referring to FIG. 5, FIG. 5 is a structural schematic diagram of a first section of a display panel according to an embodiment of the present application.

Referring to FIGS. 2-5, in some embodiments, the orthographic projection of the support portion 512 on the substrate 1 has an annular shape, the connecting region 510 is connected to the second section 52, to make the first section 51 and the second section 52 define the void space 500 in an enclosing manner.

In one embodiment, the orthographic projection of the support portion 512 on the substrate 1 having an annular shape may refer to that the orthographic projection of the support portion 512 on the substrate 1 in the form of a closed ring, to facilitate formation of a sealed void space 500. In one embodiment, the void space 500 is of a closed structure, where the sealed void space 500 defined by the first section 51 and the second section 52 in an enclosing manner may not be in communication with other external spaces, to further improve the structural stability of the first section 51 and the second section 52.

In one embodiment, the orthographic projection of the support portion 512 on the substrate 1 may surround the orthographic projection of the pixel opening 22 on the substrate 1. In one embodiment, the orthographic projection of the second section 52 on the substrate 1 may surround the orthographic projection of the support portion 512 on the substrate 1.

In these embodiments, it is provided for the orthographic projection of the support portion 512 on the substrate 1 to have an annular shape, and an increased connecting area between the support portion 512 within the isolation opening 30 and the second section 52 around the isolation structure 3 is provided, that is, the support portion 512 within the isolation opening 30 may better support the second section 52 around a periphery of the isolation structure 3, thereby better improving the supporting effect of the support portion 512 on the second section 52, making the first section 51 less likely to be detached from the isolation structure 3, and better improving the encapsulation effect of the first encapsulation layer 5 on the display panel.

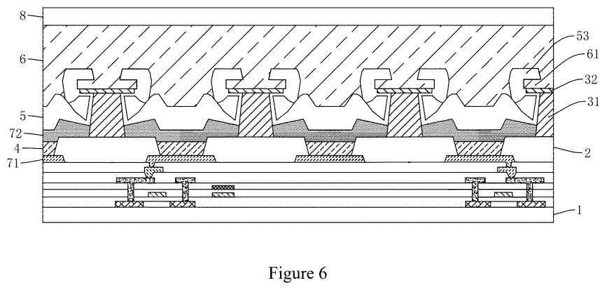

Referring to FIG. 6, FIG. 6 is a partial sectional view of a display panel according to yet another embodiment of the present application.

Referring to FIG. 6, in some embodiments, the encapsulation portion 50 further includes a third section 53. The third section 53 is located on a side of the second sub-layer 32 away from the substrate 1. An end of the second section 52 extends away from the substrate 1 and is connected to the third section 53. The third section 53 is spaced apart from the isolation structure 3. The third section 53 located on a side of the isolation structure 3 away from the substrate 1 can better improve a path for moisture ingress toward the light-emitting unit 41, thereby better improving the encapsulation effect of the first encapsulation layer 5 on the light-emitting units 41. In one embodiment, the third section 53 is connected to an end of the second section 52 away from the substrate 1.

In one embodiment, a support structure 61 may be filled between the third section 53 and the isolation structure 3. The support structure 61 filled between the third section 53 and the isolation structure 3 may function to well limit the third section 53. For example, the support structure 61 filled between the third section 53 and the isolation structure 3 may be used to support the third section 53, and the third section 53 is not likely to be broken or detached toward the isolation structure 3, thereby better improving the structural stability of the first encapsulation layer 5.

In one embodiment, at least part of the material of the second encapsulation layer 6 may extend between the third section 53 and the isolation structure 3 to form the support structure 61, and the part of the material of the second encapsulation layer 6 may also be used to support the third section 53.

In one embodiment, at least part of the second encapsulation layer 6 may also be located on a side of the third section 53 away from the isolation structure 3, and the third section 53 to be effectively wrapped by the second encapsulation layer 6 to further improve the limiting of the second encapsulation layer 6 on the third section 53, and the second encapsulation layer 6 may restrict the third section 53 from being broken and detached toward the pixel opening 22, thereby better improving the structural stability of the first encapsulation layer 5.

Referring to FIGS. 1 to 6 together, an embodiment of the first aspect of the present application further provides a display panel, including a substrate 1, a pixel defining layer 2, an isolation structure 3, a light-emitting layer 4, and a first encapsulation layer 5. The pixel defining layer 2 includes pixel defining portions 21 located on a side of the substrate 1, and pixel openings 22. The isolation structure 3 is disposed on a side of the pixel defining portions 21 away from the substrate 1 and defines isolation openings 30 in an enclosing manner. Orthographic projections of the pixel openings 22 on the substrate 1 are located within orthographic projections of the isolation openings 30 on the substrate 1. The isolation structure 3 includes a first sub-layer 31 and a second sub-layer 32 located on a side of the first sub-layer 31 away from the substrate 1. The first sub-layer 31 includes a top surface 311 away from the substrate 1 and sidewalls facing the openings. The second sub-layer 32 protrudes from the sidewalls toward the isolation openings 30. The light-emitting layer 4 includes light-emitting units 41 which are at least partially located within the pixel openings 22. The first encapsulation layer 5 includes encapsulation portions 50 for encapsulating the light-emitting units 41. Each of the encapsulation portions 50 includes a first section 51 and a second section 52 that are connected to each other. The first section 51 is located within the isolation opening 30 and disposed on a side of the light-emitting unit 41 away from the substrate 1, and the second section 52 is located on a side of the isolation structure 3 facing the isolation opening 30. A surface of a side of the first section 51 away from the substrate 1 and a surface of a side of the second section 52 away from the isolation structure 3 are at least partially connected to define a void space 500 in an enclosing manner. where the pixel defining portion 21 has a first orthographic projection on the substrate 1, the second sub-layer 32 has a second orthographic projection on the substrate 1, and the first orthographic projection includes a projection portion located outside the second orthographic projection. An orthographic projection of the second section 52 on the substrate 1 has a third boundary 5300 facing the isolation openings 30, and the third boundary 5300 is located within the projection portion.

An embodiment of the present application further provides a display panel. The display panel includes a substrate 1, a pixel defining layer 2, an isolation structure 3, light-emitting units 41, and a first encapsulation layer 5. The pixel defining portions 21 are disposed on a side of the substrate 1. The isolation structure 3 is disposed on a side of the pixel defining portions 21 away from the substrate 1 and defines the isolation openings 30 in an enclosing manner. The orthographic projections of the pixel openings 22 on the substrate 1 are located within the orthographic projections of the isolation openings 30 on the substrate 1. The light-emitting units 41 are at least partially located within the pixel openings 22. The isolation structure 3 is used to divide subpixels of the display panel. The isolation structure 3 is disposed on the substrate 1 and defines the isolation openings 30 in an enclosing manner to separate the light-emitting layer 4 into the light-emitting units 41 that are disconnected from each other, thereby reducing crosstalk between charge carriers in the light-emitting layer 4 and improving the display effect of the display panel. Moreover, the light-emitting units 41 may be prepared without the use of a precision mask, which can reduce the development and use of the precision mask and lower preparation costs.

A recess is formed in a region where each pixel opening 22 is located. Structures such as the light-emitting units 41 and the first encapsulation layer 5 adaptively conform to the recesses of the pixel openings 22 when being deposited on the pixel defining layer 2. When the connection between the second section 52 and the first section 51 is located in a recessed region of the first section 51, with the influences from the recessed structure, the connecting region 510 is arranged away from the second section 52, which is likely to lead to connection failure between the first section 51 and the second section 52 and thus encapsulation failure of the first encapsulation layer 5. In the embodiments of the present application, the third boundary 5300 is defined to be located within the projection portion, that is, the third boundary 5300 is located directly above the pixel defining portion 21, the recess of the pixel opening 22 is avoided, improving the encapsulation reliability of the first encapsulation layer 5.

In one embodiment, the orthographic projection of the void space 500 on the substrate 1 has the first boundary 5100 away from the isolation structure 3 may be understood as that: a junction between the surface of the side of the first section 51 away from the substrate 1 and the surface of the side of the second section 52 away from the isolation structure 3 is defined as a connecting region 510, where an orthographic projection of the connecting region 510 on the substrate 1 includes two boundaries, where the boundary closer to the isolation structure 3 coincides with the first boundary 5100, that is, the two boundaries are the same boundary.

In some embodiments, within the same isolation opening 30, the orthographic projection of the void space 500 on the substrate 1 has a first boundary 5100 away from the isolation structure 3, an orthographic projection of the top surface 311 on the substrate 1 has a second boundary 5200, a distance between the first boundary 5100 and the second boundary 5200 is b, and a distance between the third boundary 5300 and the second boundary 5200 is c, where b<c.

In these embodiments, by defining that b is less than c, the connection between the second section 52 and the first section 51 can avoid a region where the pixel opening 22 is located in the thickness direction of the display panel. That is, the orthographic projection of the connecting region 510 on the substrate 1 and an orthographic projection of the pixel opening 22 on the substrate 1 have no overlap therebetween. As a result, the connecting region 510 is mainly located above the flat pixel defining portion 21, which reduces influences of the pixel opening 22 structure on the sealed structure formed by the connection between the second section 52 and the first section 51, to enable the first section 51 to more stably support the second section 52, improving the encapsulation reliability of the first encapsulation layer 5 and thus the yield and usage performance of the display panel.

In one embodiment, the orthographic projection of the connecting region 510 on the substrate 1 further includes a fourth boundary 5400. The fourth boundary 5400 is located on a side of the first boundary 5100 away from the isolation structure 3, and a distance between the fourth boundary 5400 and the second boundary 5200 is d, where d≤c. In one embodiment, both the first boundary 5100 and the fourth boundary 5400 are annular in shape, with the fourth boundary 5400 located inside the first boundary 5100, that is, the fourth boundary 5400 has a smaller size than the first boundary 5100, and the first boundary 5100 is located closer to the isolation structure 3 than the fourth boundary 5400.

In these embodiments, by defining d≤c, the connecting regions 510 can be located on the pixel defining portions 21, thereby avoiding the pixel openings 22. That is, the connecting regions 510 are located above the pixel defining portions 21, to enable the first sections 51 to more stably support the second sections 52, and improve the encapsulation reliability of the first encapsulation layer 5 and thus the yield and usage performance of the display panel.

In one embodiment, the display panel further provided in the embodiments of the first aspect of the present application may be the display panel according to any of the preceding embodiments. Therefore, the display panel further provided in the embodiments of the present application may have the beneficial effects of the display panel in any of the preceding embodiments, which will not be described in detail here. For example, the substrate 1 may be the substrate 1 according to any of the preceding embodiments. For example, the encapsulation portion 50 may be the encapsulation portion 50 according to any of the preceding embodiments. For example, the display panel may further include the first electrode layer 71 and the second electrode layer 72 according to any of the preceding embodiments. For example, the isolation structure 3 may be the isolation structure 3 according to any of the preceding embodiments. The isolation structure 3 may include the first sub-layer 31, the second sub-layer 32 and the third sub-layer 33 according to any of the preceding embodiments, and the isolation structure 3 may be used to separate the material of the light-emitting layer 4 from the material of the second electrode layer 72 during preparation of the light-emitting layer 4 and the second electrode layer 72. The second electrodes 721 in adjacent isolation openings 30 may also be electrically connected to each other through the isolation structure 3 to form a continuous electrode. For example, the display panel may further include the pixel openings 22 according to any of the preceding embodiments. A size of each pixel opening 22 gradually increases along a direction away from the substrate 1, to facilitate climbing of the light-emitting unit 41 and the second electrode 721, thereby increasing a light-emitting area of the light-emitting unit 41 and forming a continuous electrode through overlaps between the second electrodes 721 and the isolation structure 3. For example, the display panel may further include the second encapsulation layer 6 and the third encapsulation layer 8 according to any of the preceding embodiments, to improve flatness of the display panel and further improve the encapsulation effect.

An embodiment of a second aspect of the present application provides a display device, including a display panel of any of the above embodiments. Since the display device according to the embodiment of the second aspect of the present application includes the display panel according to any one of the above embodiments of the first aspect, the display device according to the embodiment of the second aspect of the present application has the beneficial effects of the display panel according to any one of the above embodiments of the first aspect, and will not be described in detail here.

The display device in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present disclosure to only the described specific embodiments. Apparently, many modifications and variations can be made in light of the above description. The embodiments are selected and described in this specification to better explain the principles and practical applications of the present disclosure. The present application is limited only by the claims and all the scopes and equivalents thereof.

What is claimed is:

1. A display panel, comprising:
a substrate;
an isolation structure disposed on a side of the substrate and defining a plurality of isolation openings in an enclosing manner, wherein the isolation structure comprises a first sub-layer and a second sub-layer located on a side of the first sub-layer away from the substrate, the first sub-layer comprising a top surface away from the substrate and a sidewall facing one of the isolation openings, and the second sub-layer protruding from the sidewall toward the isolation opening by a length a;
a plurality of light-emitting units, wherein the light-emitting units are at least partially located within the isolation openings; and
a first encapsulation layer comprising a plurality of encapsulation portions, wherein each of the encapsulation portions comprises a first section and a second section that are connected to each other, the first section is located within the isolation opening and disposed on a side of the light-emitting unit away from the substrate, the second section is located on a side of the isolation structure facing the isolation opening, and a surface of a side of the first section away from the substrate and a surface of a side of the second section away from the isolation structure are at least partially connected to define a void space in an enclosing manner,
wherein within the same isolation opening, an orthographic projection of the void space on the substrate has a first boundary away from the isolation structure, an orthographic projection of the top surface on the substrate has a second boundary, and a distance between the first boundary and the second boundary is b, wherein b>a.

2. The display panel according to claim 1, wherein 1.5a≤b≤2.5a.

3. The display panel according to claim 1, wherein b=2a.

4. The display panel according to claim 1, wherein the display panel further comprises a pixel defining portion disposed on a side of the isolation structure close to the substrate, wherein
the pixel defining portion has a first orthographic projection on the substrate, the second sub-layer has a second orthographic projection on the substrate, and the first orthographic projection comprises a projection portion outside the second orthographic projection; and
an orthographic projection of the second section on the substrate has a third boundary facing the isolation opening, and the third boundary is located within the projection portion.

5. The display panel according to claim 4, wherein within the same isolation opening, a distance between the third boundary and the second boundary is c, wherein b<c.

6. The display panel according to claim 5, wherein an junction between the surface of the side of the first section away from the substrate and the surface of the side of the second section away from the isolation structure is defined as a connecting region, wherein an orthographic projection of the connecting region on the substrate comprises the first boundary and a fourth boundary, the fourth boundary is located on a side of the first boundary away from the isolation structure, and a distance between the fourth boundary and the second boundary is d, wherein d≤c.

7. The display panel according to claim 4, wherein the first section comprises a main body portion and a support portion, wherein the support portion is located on a side of the main body portion away from the substrate and extends toward the second section, and the support portion is connected to the second section;
an end of the main body portion facing the isolation structure is connected to an end of the second section facing the substrate;
the pixel defining portion defines a plurality of pixel openings in an enclosing manner, wherein each of the pixel openings is in communication with a corresponding isolation opening, and an opening area of the pixel opening gradually increases along a direction away from the substrate; and
the main body portion comprises a first sub-portion and a second sub-portion, wherein an orthographic projection of the first sub-portion on the substrate is located within an orthographic projection of the pixel opening on the substrate; and
an orthographic projection of the second sub-portion on the substrate is located within an orthographic projection of the pixel defining portion on the substrate.

8. The display panel according to claim 7, wherein the second section comprises a first portion disposed on a side of the second sub-layer facing the isolation openings, wherein the support portion is connected to the first portion to define the void space in an enclosing manner, and the first portion extends toward a side away from the substrate; and
at least part of the void space is located between the second sub-layer and the substrate.

9. The display panel according to claim 8, wherein the second section further comprises a second portion disposed on a side of the first sub-layer facing the isolation openings, wherein
first portion is spaced apart from the main body portion, the second portion is spaced apart from the support portion, and the first portion, the second portion, the support portion and the main body portion define the void space in an enclosing manner.

10. The display panel according to claim 1, wherein the encapsulation portion further comprises a third section, wherein the third section is located on a side of the second sub-layer away from the substrate, an end of the second section extends away from the substrate and is connected to the third section, the third section is spaced apart from the isolation structure, and a support structure is filled between the third section and the isolation structure;
the display panel further comprises a second encapsulation layer disposed on a side of the first encapsulation layer away from the substrate, wherein at least part of a material of the second encapsulation layer extends between the third section and the isolation structure to form the support structure;
at least part of the second encapsulation layer is located on a side of the third section away from the isolation structure; and
a material of the first encapsulation layer comprises an inorganic material, and the material of the second encapsulation layer comprises an organic material.

11. The display panel according to claim 1, wherein the isolation structure further comprises a third sub-layer disposed on a side of the first sub-layer facing the substrate, wherein the third sub-layer protrudes toward the isolation openings beyond the first sub-layer; and
the void space is an closed structure.

12. A display panel, comprising:
a substrate;
a pixel defining portion disposed on a side of the substrate;
an isolation structure located on a side of the pixel defining portions away from the substrate and defining a plurality of isolation openings in an enclosing manner, wherein the isolation structure comprises a first sub-layer and a second sub-layer located on a side of the first sub-layer away from the substrate, the first sub-layer comprising a top surface away from the substrate and sidewalls facing the isolation openings, and the second sub-layer protruding from the sidewalls toward the isolation openings;
a plurality of light-emitting units, wherein the light-emitting units are at least partially located within the isolation openings; and
a first encapsulation layer comprising a plurality of encapsulation portions, wherein each of the encapsulation portions comprises a first section and a second section that are connected to each other, the first section is located within the isolation opening and disposed on a side of the light-emitting unit away from the substrate, the second section is located on a side of the isolation structure facing the isolation opening, and a surface of a side of the first section away from the substrate and a surface of a side of the second section away from the isolation structure are at least partially connected to define a void space in an enclosing manner,
wherein the pixel defining portion has a first orthographic projection on the substrate, the second sub-layer has a second orthographic projection on the substrate, and the first orthographic projection comprises a projection portion outside the second orthographic projection; and
an orthographic projection of the second section on the substrate has a third boundary facing the isolation opening, and the third boundary is located within the projection portion.

13. The display panel according to claim 12, wherein within the same isolation opening, an orthographic projection of the void space on the substrate has a first boundary away from the isolation structure, an orthographic projection of the top surface on the substrate has a second boundary, a distance between the first boundary and the second boundary is b, and a distance between the third boundary and the second boundary is c, wherein b<c.

14. The display panel according to claim 13, wherein an junction between the surface of the side of the first section away from the substrate and the surface of the side of the second section away from the isolation structure is defined as a connecting region, wherein an orthographic projection of the connecting region on the substrate comprises the first boundary and a fourth boundary, the fourth boundary is located on a side of the first boundary away from the isolation structure, and a distance between the fourth boundary and the second boundary is d, wherein d≤c.

15. The display panel according to claim 12, wherein the pixel defining portion defines a plurality of pixel openings in an enclosing manner, wherein each of the pixel openings is in communication with a corresponding isolation opening, and an opening area of the pixel opening gradually increases along a direction away from the substrate; and
the first section comprises a main body portion and a support portion, wherein the support portion is located on a side of the main body portion away from the substrate and extends toward the second section, and the support portion is connected to the second section;
an end of the main body portion facing the isolation structure is connected to an end of the second section facing the substrate;
the main body portion comprises a first sub-portion and a second sub-portion that are connected to each other, wherein an orthographic projection of the first sub-portion on the substrate is located within an orthographic projection of the pixel opening on the substrate; and an orthographic projection of the second sub-portion on the substrate is located within an orthographic projection of the pixel defining portion on the substrate.

16. The display panel according to claim 15, wherein the second section comprises a first portion disposed on a side of the second sub-layer facing the isolation openings, wherein the support portion is connected to the first portion to define the void space in an enclosing manner, and the first portion extends toward a side away from the substrate; and
at least part of the void space is located between the second sub-layer and the substrate.

17. The display panel according to claim 16, wherein the second section further comprises a second portion disposed on a side of the first sub-layer facing the isolation openings, wherein the first portion is spaced apart from the main body portion, the second portion is spaced apart from the support portion, and the first portion, the second portion, the support portion and the main body portion define the void space in an enclosing manner.

18. The display panel according to claim 12, wherein the isolation structure further comprises a third sub-layer disposed on a side of the first sub-layer facing the substrate, wherein the third sub-layer protrudes toward the isolation openings beyond the first sub-layer; and the void space is an closed structure.

19. The display panel according to claim 12, wherein the encapsulation portion further comprises a third section, wherein the third section is located on a side of the second sub-layer away from the substrate, an end of the second section extends away from the substrate and is connected to the third section, the third section is spaced apart from the isolation structure, and a support structure is filled between the third section and the isolation structure;
the display panel further comprises a second encapsulation layer disposed on a side of the first encapsulation layer away from the substrate, wherein at least part of a material of the second encapsulation layer extends between the third section and the isolation structure to form the support structure;
at least part of the second encapsulation layer is located on a side of the third section away from the isolation structure; and
a material of the first encapsulation layer comprises an inorganic material, and the material of the second encapsulation layer comprises an organic material.

20. A display device, comprising:
a display panel, comprising:
a substrate;
an isolation structure disposed on a side of the substrate and defining a plurality of isolation openings in an enclosing manner, wherein the isolation structure comprises a first sub-layer and a second sub-layer located on a side of the first sub-layer away from the substrate, the first sub-layer comprising a top surface away from the substrate and a sidewall facing one of the isolation openings, and the second sub-layer protruding from the sidewall toward the isolation opening by a length a;
a plurality of light-emitting units, wherein the light-emitting units are at least partially located within the isolation openings; and
a first encapsulation layer comprising a plurality of encapsulation portions, wherein each of the encapsulation portions comprises a first section and a second section that are connected to each other, the first section is located within the isolation opening and disposed on a side of the light-emitting unit away from the substrate, the second section is located on a side of the isolation structure facing the isolation opening, and a surface of a side of the first section away from the substrate and a surface of a side of the second section away from the isolation structure are at least partially connected to define a void space in an enclosing manner,
wherein within the same isolation opening, an orthographic projection of the void space on the substrate has a first boundary away from the isolation structure, an orthographic projection of the top surface on the substrate has a second boundary, and a distance between the first boundary and the second boundary is b, wherein b>a.
